(19) United States
(12) Patent Application Publication
(10) Pub. No.: US 2025/0143090 A1
(43) Pub. Date: May 1, 2025

(54) DISPLAY PANEL AND DISPLAY APPARATUS

(71) Applicants: Hefei Visionox Technology Co., Ltd., Hefei, Anhui (CN); KunShan Go-Visionox Opto-Electronics Co., Ltd, Kunshan, Jiangsu (CN)

(72) Inventors: Wenyu ZENG, Hefei (CN); Ying SHEN, Hefei (CN); Pengle DANG, Hefei (CN); Lixiong XU, Hefei (CN)

(73) Assignees: Hefei Visionox Technology Co., Ltd., Hefei, Anhui (CN); KunShan Go-Visionox Opto-Electronics Co., Ltd, Kunshan, Jiangsu (CN)

(21) Appl. No.: 18/748,546

(22) Filed: Jun. 20, 2024

(30) Foreign Application Priority Data
Oct. 31, 2023 (CN) 202311451674.9

(51) Int. Cl. H10K 59/122; G06F 3/041; G06F 3/044; H10K 59/40

(52) U.S. Cl. CPC H10K 59/122; G06F 3/0412; H10K 59/40; G06F 3/044; G06F 2203/04107; G06F 2203/04112

(57) ABSTRACT

The present application discloses a display panel and a display apparatus. The display panel has a first area and a second area. The display panel includes an array substrate, an isolation structure provided with light-transmitting openings and isolation openings, the isolation openings being located at least in the first area, and the light-transmitting openings being located in the second area, a light-emitting layer including light-emitting units arranged in the isolation openings, and a touch layer having a touch area and a non-touch area, the touch layer including a touch electrode arranged in the touch area and a dummy electrode arranged in the non-touch area, the touch electrode being insulated from the dummy electrode, at least part of the touch area being located in the first area, and at least part of the non-touch area being located in the second area.

### CROSS REFERENCE TO RELATED APPLICATION

The present application claims priority to Chinese Patent Application No. 202311451674.9 filed on Oct. 31, 2023, which is incorporated herein by reference in its entirety.

### TECHNICAL FIELD

The present application belongs to the technical field of displays, and in particular, to a display panel and a display apparatus.

### BACKGROUND

An organic light emitting display (OLED) and a flat display apparatus based on a light emitting diode (LED) technology are widely used in various consumer electronic products such as mobile phones, TVs, notebook computers, and desktop computers due to advantages such as high image quality, power saving, a thin body, and a wide range of applications, becoming the mainstream in display apparatuses.

However, operational performance of current OLED display products needs to be improved.

### SUMMARY

Embodiments of the present application provide a display panel and a display apparatus, intended to reduce crosstalk between signals in an array substrate and touch signals in the display panel.

Some embodiment of a first aspect of the present application provide a display panel, wherein the display panel has a first area and a second area, and the display panel includes: an array substrate; an isolation structure arranged on one side of the array substrate and provided with light-transmitting openings and isolation openings, the isolation openings being located at least in the first area, and the light-transmitting openings being located in the second area; a light-emitting layer including light-emitting units arranged in the isolation openings; and a touch layer arranged on a side of the light-emitting layer facing away from the array substrate and having a touch area and a non-touch area, the touch layer including a touch electrode arranged in the touch area and a dummy electrode arranged in the non-touch area, the touch electrode being insulated from the dummy electrode, at least part of the touch area being located in the first area, and at least part of the non-touch area being located in the second area.

Some embodiments of a second aspect of the present application provide a display apparatus including the display panel in any one of the above implementations.

The display panel according to the embodiments of the present application includes the array substrate, the isolation structure, the light-emitting layer, and the touch layer, and the display panel has the first area and the second area. The isolation structure is arranged on one side of the array substrate and provided with light-transmitting openings and isolation openings, and the light-transmitting openings are located in the second area, so that the light-transmitting openings provided in the isolation structure can improve the light transmittance of the second area of the display panel. The isolation openings provided in the isolation structure are provided with the light-emitting units, so that the isolation structure can be used to divide sub-pixels of the display panel. Moreover, the isolation openings are located at least in the first area, so that the display panel in the first area can perform light-emitting display. The touch layer is arranged on the side of the light-emitting layer facing away from the array substrate and has the touch area and the non-touch area, at least part of the touch area is located in the first area, and at least part of the non-touch area is located in the second area. The touch electrode is arranged in the touch area. The touch electrode may be configured to receive a touch signal to implement a touch function of the display panel in the first area. The touch electrode is insulated from the dummy electrode, so that the touch signal in the touch electrode is less likely to be transmitted to the dummy electrode. Moreover, the dummy electrode is arranged in the non-touch area in the second area, that is, the dummy electrode is at least partially arranged corresponding to the light-transmitting opening, so that a signal in the array substrate is less likely to crosstalk with the touch signal in the touch electrode through the light-transmitting opening and the dummy electrode, which can better improve operational reliability of the display panel.

### BRIEF DESCRIPTION OF THE DRAWINGS

FIG. 1 shows a schematic structural diagram of a display panel according to an embodiment of the present application;

FIG. 2 shows a partial sectional view of the display panel according to an embodiment of the present application;

FIG. 3 shows a schematic partial enlarged view of a touch layer and an isolation structure according to an embodiment of the present application;

FIG. 4 shows a schematic partial enlarged view of the touch layer and the isolation structure according to another embodiment of the present application;

FIG. 5 shows a schematic partial enlarged view of the touch layer and the isolation structure according to yet another embodiment of the present application;

FIG. 6 shows a schematic partial view of the isolation structure and a dummy electrode according to an embodiment of the present application;

FIG. 7 shows a schematic partial enlarged view of the isolation structure and the dummy electrode according to an embodiment of the present application;

FIG. 8 shows a schematic partial view of the isolation structure and the dummy electrode according to another embodiment of the present application;

FIG. 9 shows a schematic partial enlarged view of the isolation structure and the dummy electrode according to yet another embodiment of the present application;

FIG. 10 shows a schematic partial enlarged view of the isolation structure and the dummy electrode according to still another embodiment of the present application;

FIG. 11 shows a schematic partial enlarged view of the isolation structure and the dummy electrode according to a further embodiment of the present application;

FIG. 12 shows a partial sectional view of the display panel according to another embodiment of the present application;

FIG. 13 shows a partial sectional view of the display panel according to yet another embodiment of the present application;

FIG. 14 shows a partial sectional view of the display panel according to still another embodiment of the present application; and

FIG. 15 shows a partial sectional view of the display panel according to a further embodiment of the present application.

### REFERENCE SIGNS

10: display panel;
100: array substrate; 110: base; 120: first insulating layer; 130: second insulating layer; 140: third insulating layer; 150: driving circuit; 151: transistor; 151a: gate; 151b: source and drain; 152: storage capacitor; 152a: first plate; 152b: second plate;
200: second electrode layer; 210: second electrode;
300: isolation structure; 300a: light-transmitting opening; 300b: isolation opening; 300c: first-type opening; 300d: second-type opening; 310: isolation pillar; 310a: first end portion; 310b: second end portion; 311: first isolation portion; 312: second isolation portion; 320: pixel defining portion; 320a: pixel opening; 321: accommodating groove;
400: light-emitting layer; 410: light-emitting unit;
500: first electrode layer; 510: first electrode;
600: touch layer; 600a: touch area; 600b: non-touch area; 610: touch electrode; 620: dummy electrode; 621: first-type electrode; 622: second-type electrode; 630: insulating portion; 640: partition groove;
AA1: first area;
AA2: second area;
X: thickness direction;
Y: first direction;
Z: second direction;
J: first preset direction;
K: second preset direction;
S1: first symmetry axis;
S2: second symmetry axis;
S3: third symmetry axis;
S4: fourth symmetry axis;
L1: first spacing;
L2: second spacing.

### DETAILED DESCRIPTION

In order to better understand the present application, a display panel and a display apparatus according to the embodiments of the present application will be described in detail below with reference to the accompanying drawings.

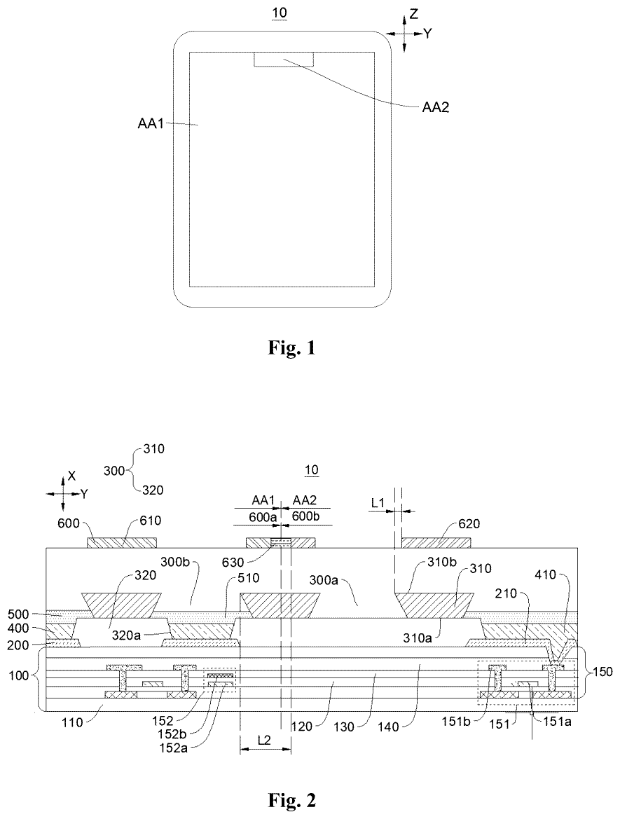

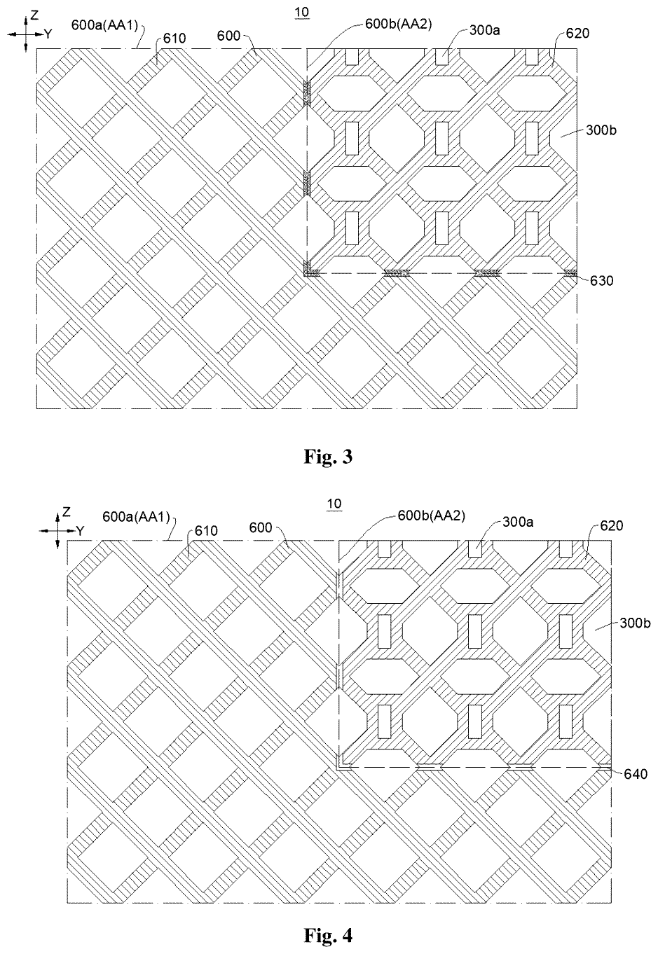

FIG. 1 shows a schematic structural diagram of a display panel 10 according to an embodiment of the present application, FIG. 2 shows a partial sectional view of the display panel 10 according to an embodiment of the present application, and FIG. 3 shows a schematic partial enlarged view of a touch layer 600 and an isolation structure 300 according to an embodiment of the present application. A direction X in the figures is a thickness direction of the display panel 10, a direction Y in the figures is a first direction, and a direction Z in the figures is a second direction. The first direction Y, the second direction Z, and the thickness direction X pairwise intersect. Optionally, the first direction Y, the second direction Z, and the thickness direction X may be pairwise perpendicular.

As shown in FIG. 1 and FIG. 2, the embodiments of a first aspect of the present application provide a display panel 10. The display panel 10 has a first area AA1 and a second area AA2. The display panel 10 includes: an array substrate 100; an isolation structure 300 arranged on one side of the array substrate 100 and provided with light-transmitting openings 300a and isolation openings 300b, the isolation openings 300b being located at least in the first area AA1, and the light-transmitting openings 300a being located in the second area AA2; a light-emitting layer 400 including light-emitting units 410 arranged in the isolation openings 300b; and a touch layer 600 arranged on a side of the light-emitting layer 400 facing away from the array substrate 100 and having a touch area 600a and a non-touch area 600b. The touch layer 600 includes a touch electrode 610 arranged in the touch area 600a and a dummy electrode 620 arranged in the non-touch area 600b, the touch electrode 610 is insulated from the dummy electrode 620, at least part of the touch area 600a is located in the first area AA1, and at least part of the non-touch area 600b is located in the second area AA2.

The display panel 10 according to the embodiments of the present application includes the array substrate 100, the isolation structure 300, the light-emitting layer 400, and the touch layer 600, and the display panel 10 has the first area AA1 and the second area AA2. The isolation structure 300 is arranged on one side of the array substrate 100 and provided with light-transmitting openings 300a and isolation openings 300b, and the light-transmitting openings 300a are located in the second area AA2, so that the light-transmitting openings 300a provided in the isolation structure 300 can improve the light transmittance of the second area AA2 of the display panel 10. The isolation openings 300b provided in the isolation structure 300 are provided with the light-emitting units 410, so that the isolation structure 300 can be used to divide sub-pixels of the display panel 10. Moreover, the isolation openings 300b are located at least in the first area AA1, so that the display panel 10 in the first area AA1 can perform light-emitting display. The touch layer 600 is arranged on the side of the light-emitting layer 400 facing away from the array substrate 100 and has the touch area 600a and the non-touch area 600b, at least part of the touch area 600a is located in the first area AA1, and at least part of the non-touch area 600b is located in the second area AA2. The touch electrode 610 is arranged in the touch area 600a. The touch electrode 610 may be configured to receive a touch signal to implement a touch function of the display panel 10 in the first area AA1. The touch electrode 610 is insulated from the dummy electrode 620, so that the touch signal in the touch electrode 610 is less likely to be transmitted to the dummy electrode 620. Moreover, the dummy electrode 620 is arranged in the non-touch area 600b in the second area AA2, that is, the dummy electrode 620 is at least partially arranged corresponding to the light-transmitting opening 300a, so that a signal in the array substrate 100 is less likely to crosstalk with the touch signal in the touch electrode 610 through the light-transmitting opening 300a and the dummy electrode 620, which can better improve operational reliability of the display panel 10.

In some embodiments of the present application, the signal in the array substrate 100 may refer to a signal likely to crosstalk to the dummy electrode 620 through the light-transmitting opening 300a. For example, the signal in the array substrate 100 may be a light-emitting driving signal, a light-emitting control signal, or the like.

The array substrate 100 may be arranged in a variety of manners. The array substrate 100 may include, for example, a base 110 and a driving circuit 150 arranged on the base 110. Optionally, the signal in the array substrate 100 may refer to a signal in the driving circuit 150. Optionally, the array substrate 100 may further include a first insulating layer 120, a second insulating layer 130, and a third insulating layer 140 that are stacked. For example, the driving circuit 150 may include a transistor 151, a storage capacitor 152, driving signal lines for connecting various devices, and the like. The transistor 151 includes a semiconductor, a gate 151a, and a source-drain 151b. The storage capacitor 152 includes a first plate 152a and a second plate 152b. As an example, the gate 151a and the first plate 152a may be located on a side of the first insulating layer 120 facing the base 110, the second plate 152b may be located between the first insulating layer 120 and the second insulating layer 130, and the source-drain 151b may be located between the second insulating layer 130 and the third insulating layer 140.

Optionally, a plurality of isolation openings 300b may be provided, and each isolation opening 300b is provided with the light-emitting unit 410. For example, one isolation opening 300b is provided with at least one light-emitting unit 410. Optionally, the light-emitting unit 410 may include a hole inject layer (HIL), a hole transport layer (HTL), a light-emitting structure, an electron inject layer (EIL), and an electron transport layer (ETL).

Optionally, the display panel 10 further includes a first electrode layer 500, and the first electrode layer 500 includes at least two first electrodes 510 arranged in the isolation opening 300b and located on a side of the light-emitting unit 410 facing away from the array substrate 100.

Optionally, the display panel 10 further includes a second electrode layer 200, the second electrode layer 200 includes at least two second electrodes 210 arranged at intervals, and the second electrodes 210 may be located on a side of the light-emitting unit 410 facing the array substrate 100.

In these optional embodiments, the first electrode layer 500 and the second electrode layer 200 may be used as pixel electrode layers of the display panel 10, one of the first electrode 510 and the second electrode 210 is used as an anode, and the other may be used as a cathode to drive the light-emitting unit 410 to emit light. The embodiments of the present application are illustrated based on an example in which the first electrode 510 is a cathode of the display panel 10 and the second electrode 210 is an anode of the display panel 10.

In some embodiments of the present application, the touch electrode 610 may be arranged in a variety of forms. The touch electrode 610 of the present application may be a mutual-capacitance-based touch electrode 610 or a self-capacitance-based touch electrode 610. Optionally, the touch electrode 610 and the dummy electrode 620 may include a multi-layer structure (not shown). At least part of the touch electrode 610 may be arranged in the same layer as at least part of the dummy electrode 620, to facilitate manufacturing of the touch electrode 610 and the dummy electrode 620.

In some optional embodiments, the isolation structure 300 may be a mesh in shape, and a hollow area in the mesh isolation structure 300 may be the isolation opening 300b and the light-transmitting opening 300a.

As shown in FIG. 1 to FIG. 3, in some optional embodiments, a light transmittance of the second area AA2 is greater than a light transmittance of the first area AA1.

Optionally, one or two or more light-transmitting openings 300a are provided, and at least two light-transmitting openings 300a are arranged at intervals.

The second area AA2 may be correspondingly provided with a sensor. The sensor may include at least one of an ambient light sensor, a camera, or a fingerprint sensor, and the like. The second area AA2 may have a display function or may not have a display function, which is not specifically limited herein.

The light-transmitting opening 300a located in the second area AA2 and provided in the isolation structure 300 can better allow light to pass through, so as to improve the light transmittance of the display panel 10, so that when the display panel 10 is applied to a display apparatus, a photosensitive component configured to sense light in the display apparatus may be correspondingly arranged under the light-transmitting opening 300a. Therefore, the photosensitive component can better sense light through the light-transmitting opening 300a.

Optionally, the first electrode 510, the light-emitting unit 410, and the second electrode 210 may not be arranged in the light-transmitting opening 300a, so that the display panel 10 can have a better light transmittance at the light-transmitting opening 300a.

Optionally, the light-transmitting opening 300a may be arranged only in the second area AA2. That is, the light-transmitting opening 300a may not be arranged in the first area AA1, so that the second area AA2 in the display panel 10 can have a better light transmittance and the first area AA1 in the display panel 10 can have a relatively sufficient area to arrange the isolation opening 300b. Therefore, the first area AA1 can have a larger number of isolation openings 300b, that is, the first area AA1 can have denser sub-pixels, which can better increase pixels per inch (PPI) of the first area AA1, thereby better improving a display effect of the display panel 10. Moreover, since the light-transmitting opening 300a is not arranged in the first area AA1, the signal in the array substrate 100 is less likely to crosstalk with the touch signal in the first area AA1, thereby better improving the operational reliability of the display panel 10.

Optionally, the isolation opening 300b may also be located in the second area AA2. That is, the isolation openings 300b may be located in the first area AA1 and the second area AA2.

Optionally, the isolation openings 300b in the first area AA1 and the second area AA2 are all provided with the light-emitting units 410. For example, the isolation openings 300b in the first area AA1 and the second area AA2 are all provided with the first electrode 510, the light-emitting unit 410, and the second electrode 210, so that both the first area AA1 and the second area AA2 have sub-pixels capable of emitting light, thereby better increasing a screen-to-body ratio of the display panel 10.

The isolation openings 300b may be sized and shaped in a variety of manners. Optionally, the isolation openings 300b may be sized and shaped according to light-emitting colors of the light-emitting units 410 in the isolation openings 300b. Alternatively, the isolation openings 300b may be sized and shaped according to a requirement for the PPI of the display panel 10.

As shown in FIG. 2 and FIG. 3, in some optional embodiments, in the second area AA2, the light-transmitting opening 300a may be located between two adjacent isolation openings 300b.

Optionally, at least two light-transmitting openings 300a are arranged at intervals in the first direction Y, or the at least two light-transmitting openings 300a are arranged at intervals in the second direction Z.

The positions of the light-transmitting openings 300a are arranged reasonably, so that the light-transmitting openings 300a not provided with related light-emitting devices are less likely to be arranged in a concentrated manner, which can better improve display uniformity of the display panel 10.

In some optional embodiments, the touch electrode 610 may be connected to a touch signal line of the display panel 10 to receive a touch signal, so that the touch electrode 610 in the touch area 600a can participate in touch sensing of the display panel 10.

Optionally, the touch area 600a may be arranged in the first area AA1, so that the display panel 10 in the first area AA1 can have a touch sensing function through the touch electrode 610 in the touch area 600a, and the touch electrode 610 in the touch area 600a is less likely to interference with the signal in the array substrate 100 leaking through the light-transmitting opening 300a in the second area AA2.

In some optional embodiments, the dummy electrode 620 may not be connected to the touch signal line. That is, the dummy electrode 620 in the non-touch area 600b does not participate in the touch sensing of the display panel 10.

Optionally, a dimension of the dummy electrode 620 in the thickness direction X of the display panel 10 may be equal to a dimension of the touch electrode 610 in the thickness direction X of the display panel 10.

The dummy electrode 620 is arranged in the non-touch area 600b, so that the touch layer 600 in the touch area 600a and the touch layer 600 in the non-touch area 600b can have a similar film thickness, the display panel 10 can have better flatness, there is no excessive reflectivity or a visual color shift difference between the touch area 600a and the non-touch area 600b, and the display panel 10 can have better optical image quality and display uniformity. Moreover, the dummy electrode 620 arranged in the non-touch area 600b can also play a certain role in blocking and shielding the crosstalk between the touch signal and the signal in the array substrate 100, and can improve light-emitting stability and touch stability of the display panel 10.

Optionally, at least part of the non-touch area 600b may be arranged in the second area AA2. Optionally, an orthographic projection of an inner wall of the isolation structure 300 enclosing the light-transmitting opening 300a on the touch layer 600 is located within the non-touch area 600b.

In these optional embodiments, by reasonably setting a positional relationship between the second area AA2 and the non-touch area 600b or by reasonably setting a positional relationship between the light-transmitting opening 300a and the non-touch area 600b, the non-touch area 600b can better cover the second area AA2 or be above the light-transmitting opening 300a, so that the dummy electrode 620 can play a certain role in blocking and shielding the signal in the array substrate 100 easily leaking through the light-transmitting opening 300a in the second area AA2, and the signal in the array substrate 100 leaking through the light-transmitting opening 300a in the second area AA2 is less likely to crosstalk with the touch signal in the touch electrode 610 in the touch area 600a.

In some embodiments, the second area AA2 of the display panel 10 may be configured to allow light to better pass through, so that the light can be sensed by the photosensitive component. Optionally, the second area AA2 may be configured to allow light to better pass through, to facilitate sensing by the sensor, for example, an infrared light emitting diode (IR-LED) proximity sensor on one side of the display panel 10.

Optionally, a plurality of second areas AA2 may be provided in the display panel 10, so that when at least two photosensitive components are provided in the display apparatus, each photosensitive component may be separately arranged under different second areas AA2 or the non-touch area 600b, so that the photosensitive components under different second areas AA2 can better sense light through the light-transmitting opening 300a, and the signal in the array substrate 100 is less likely to crosstalk with the touch signal at the dummy electrode 620 in the non-touch area 600b.

For example, at least part of the second areas AA2 may also be configured to allow the light to better pass through, to facilitate sensing by an under-screen fingerprint recognition module on one side of the display panel 10.

Optionally, the touch area 600a is arranged around at least part of the non-touch area 600b, so that there is a good arrangement position relationship between the touch area 600a and the non-touch area 600b, and the touch layer 600 of the display panel 10 can have a large-area touch area 600a to participate in the touch.

In some optional embodiments, an orthographic projection of the dummy electrode 620 on the array substrate 100 is within an orthographic projection of the isolation structure 300 on the array substrate 100, so that the dummy electrode 620 is less likely to block the isolation opening 300b and the light-transmitting opening 300a provided in the isolation structure 300 in the thickness direction X of the display panel 10. Therefore, the arrangement of the dummy electrodes 620 is less likely to block the light-emitting display of the display panel 10, and the dummy electrode 620 is less likely to affect the light transmittance of the display panel 10 at the light-transmitting opening 300a.

In some optional embodiments, an orthographic projection of the touch electrode 610 on the array substrate 100 is within the orthographic projection of the isolation structure 300 on the array substrate 100, so that the touch electrode 610 is less likely to block the isolation opening 300b provided in the isolation structure 300 in the thickness direction X of the display panel 10. Therefore, the arrangement of the touch electrode 610 is less likely to block the light-emitting display of the display panel 10.

In some optional embodiments, an orthographic projection of the dummy electrode 620 on the isolation structure 300 is arranged around at least part of the isolation opening 300b, or the orthographic projection of the dummy electrode 620 on the isolation structure 300 is arranged around at least part of the light-transmitting opening 300a, so that the dummy electrode 620 can have a better wiring area while the dummy electrode 620 is less likely to block the light-emitting display of the display panel 10 and is less likely to affect the light transmittance of the display panel 10 at the light-transmitting opening 300a, thereby improving the blocking and shielding effects of the dummy electrode 620 on the crosstalk between the touch signal and the signal in the array substrate 100.

Optionally, the dummy electrode 620 is a mesh in shape. A hollow area in the dummy electrode 620 in the mesh may be arranged corresponding to the light-transmitting opening 300a and the isolation opening 300b. That is, the hollow area in the mesh dummy electrode 620 may be located on sides of the light-transmitting opening 300a and the isolation opening 300b facing away from the array substrate 100 in the thickness direction X of the display panel 10.

Optionally, the orthographic projection of the touch electrode 610 on the isolation structure 300 is arranged around at least part of the isolation opening 300b, so that the touch electrode 610 may also have a better wiring area while the touch electrode 610 is less likely to shield the light-emitting display of the display panel 10, thereby improving a touch sensing capability of the display panel 10.

Optionally, the touch electrode 610 is a mesh in shape. A hollow area in the mesh touch electrode 610 may be arranged corresponding to the isolation opening 300b. That is, the hollow area in the mesh touch electrode 610 may be located on a side of the isolation opening 300b facing away from the array substrate 100 in the thickness direction X of the display panel 10.

Optionally, when an orthographic projection of the dummy electrode 620 on the isolation structure 300 is arranged around at least part of the isolation opening 300b and the orthographic projection of the touch electrode 610 on the isolation structure 300 is arranged around at least part of the isolation opening 300b, an extension shape of the touch electrode 610 may be similar to an extension shape of the dummy electrode 620. For example, both the dummy electrode 620 and the touch electrode 610 may be mesh in shape, so that there is no excessive reflectivity or a visual color shift difference between the touch area 600a and the non-touch area 600b, and the display panel 10 can have better optical image quality and display uniformity.

Optionally, a width of the dummy electrode 620 or the touch electrode 610 may be less than or equal to a width of the isolation structure 300. Optionally, the width of the dummy electrode 620 may refer to a distance between two side surfaces of the dummy electrode 620 facing the isolation opening 300b, or the width of the dummy electrode 620 may refer to a distance between two side surfaces of the dummy electrode 620 facing the light-transmitting opening 300a. Optionally, the width of the touch electrode 610 may refer to a distance between two side surfaces of the touch electrode 610 facing the isolation opening 300b. Optionally, the width of the isolation structure 300 may refer to a distance between two side surfaces of the isolation structure 300 facing the isolation opening 300b, or the width of the isolation structure 300 may refer to a distance between two side surfaces of the isolation structure 300 facing the light-transmitting opening 300a.

Optionally, the width of the touch electrode 610 may be equal to a maximum width of the isolation structure 300, so that the touch electrode 610 can have a better width to transmit the touch signal, improving the touch sensing capability of the display panel 10.

Optionally, a distance between the orthographic projection of the dummy electrode 620 on the isolation structure 300 and the light-transmitting opening 300a is greater than or equal to 1.5 μm, or a minimum spacing between the orthographic projection of the dummy electrode 620 on the isolation structure 300 and the isolation opening 300b is greater than or equal to 1.5 μm. For example, as shown in FIG. 3, the distance between the orthographic projection of the dummy electrode 620 on the isolation structure 300 and the light-transmitting opening 300a may be a first spacing L1, the minimum spacing between the orthographic projection of the dummy electrode 620 on the isolation structure 300 and the isolation opening 300b may be a second spacing L2, and both the first spacing L1 and the second spacing L2 may be greater than or equal to 1.5 μm. Therefore, the problem of easy blocking of the light-transmitting opening 300a or the isolation opening 300b when a manufacturing process of the dummy electrode 620 varies can be alleviated, which helps to ensure a product yield, thereby improving a display effect and light transmittance of the second area AA2.

As shown in FIG. 2 and FIG. 3, in some embodiments of the present application, the touch electrode 610 and the dummy electrode 620 may be insulated in a variety of manners.

In some optional embodiments, the touch layer 600 may include an insulating portion 630 arranged between the touch electrode 610 and the dummy electrode 620. Optionally, a material of the insulating portion 630 may include an insulating material. The insulating portion 630 is arranged between the touch electrode 610 and the dummy electrode 620, so that the touch electrode 610 and the dummy electrode 620 can be insulated from each other through the insulating portion 630. Therefore, the touch signal in the touch electrode 610 is less likely to crosstalk with the signal in the array substrate 100 through the dummy electrode 620.

Optionally, the insulating portion 630 is arranged around at least part of the non-touch area 600b. For example, the insulating portion 630 may be arranged between the touch area 600a and the non-touch area 600b.

Optionally, an orthographic projection of the insulating portion 630 on the array substrate 100 may be located within the orthographic projection of the isolation structure 300 on the array substrate 100, so that the insulating portion 630 may be disconnected on a side of the isolation opening 300b facing away from the substrate and the insulating portion 630 is less likely to block the isolation opening 300b provided in the isolation structure 300 in the thickness direction X of the display panel 10. Therefore, the arrangement of the insulating portion 630 630 is less likely to block the light-emitting display of the display panel 10.

Optionally, a dimension of the insulating portion 630 in the thickness direction X of the display panel 10 may be equal to the dimension of the touch electrode 610 in the thickness direction X of the display panel 10, or the dimension of the insulating portion 630 in the thickness direction X of the display panel 10 may be equal to the dimension of the dummy electrode 620 in the thickness direction X of the display panel 10, so that the touch layer 600 can have a relatively uniform thickness and the display panel 10 can have better flatness.

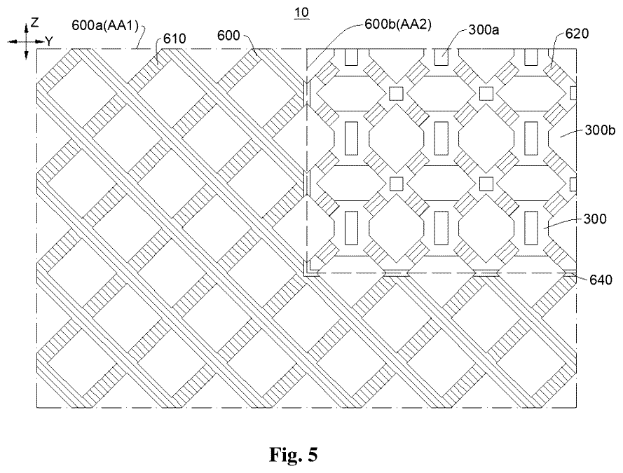

FIG. 4 shows a schematic partial enlarged view of the touch layer 600 and the isolation structure 300 according to another embodiment of the present application.

As shown in FIG. 4, in some other optional embodiments, the touch layer 600 may further include a partition groove 640 arranged between the touch electrode 610 and the dummy electrode 620. Optionally, the partition groove 640 may be arranged through the touch layer 600.

The partition groove 640 is arranged between the touch electrode 610 and the dummy electrode 620, so that the touch electrode 610 and the dummy electrode 620 can be insulated from each other through the partition groove 640. Therefore, the touch signal in the touch electrode 610 is less likely to crosstalk with the signal in the array substrate 100 through the dummy electrode 620.

Optionally, the partition groove 640 is arranged around at least part of the non-touch area 600b. For example, the partition groove 640 may be arranged between the touch area 600a and the non-touch area 600b.

FIG. 5 shows a schematic partial enlarged view of the touch layer 600 and the isolation structure 300 according to yet another embodiment of the present application.

As shown in FIG. 5, in some optional embodiments, at least two dummy electrodes 620 may be provided, and adjacent dummy electrodes 620 are arranged at intervals. A plurality of dummy electrodes 620 are provided and arranged at intervals, which can better facilitate the arrangement of the dummy electrodes 620.

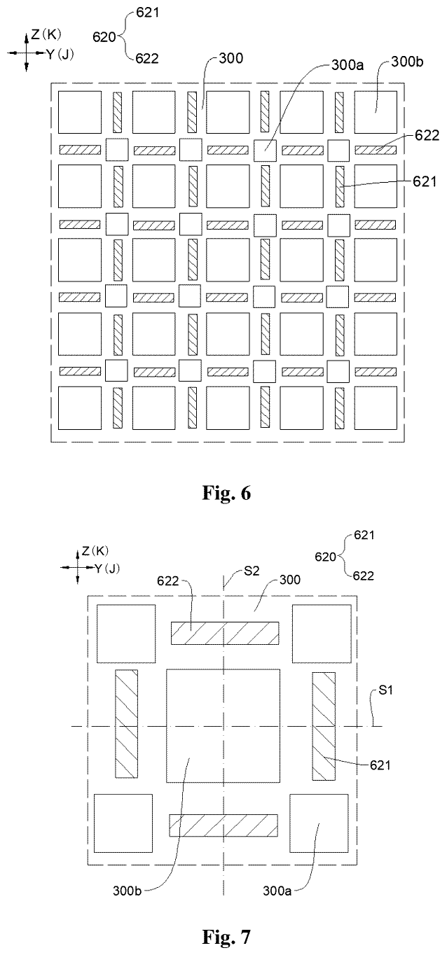

FIG. 6 shows a schematic partial view of the isolation structure 300 and the dummy electrode 620 according to an embodiment of the present application, and FIG. 7 shows a schematic partial enlarged view of the isolation structure 300 and the dummy electrode 620 according to an embodiment of the present application.

As shown in FIG. 6 and FIG. 7, in some optional embodiments, a plurality of isolation openings 300b are distributed at intervals in a first preset direction J and a second preset direction K, one part of the dummy electrodes 620 are located between the isolation openings 300b adjacent in the first preset direction J, and the other part of the dummy electrodes 620 are located between the isolation openings 300b adjacent in the second preset direction K. The first preset direction J intersects the second preset direction K. Optionally, the first preset direction J may be perpendicular to the second preset direction K.

For example, the dummy electrodes 620 include first-type electrodes 621 and second-type electrodes 622, the first-type electrodes 621 are located between the isolation openings 300b adjacent in the first preset direction J, and the second-type electrodes 622 are located between the isolation openings 300b adjacent in the second preset direction K.

In the optional embodiments, through the reasonable distribution of the isolation openings 300b, the size of the display panel 10 can be better utilized, to better improve compactness of arrangement of the isolation openings 300b and the light-emitting units 410 in the isolation openings 300b. Moreover, the dummy electrodes 620 are distributed along an arrangement direction of the isolation openings 300b and arranged between adjacent isolation openings 300b, to better utilize the size of the isolation structure 300 between the adjacent isolation openings 300b in the first preset direction J and the second preset direction K to arrange the dummy electrodes 620, thereby improving compactness of arrangement of the isolation openings 300b and the dummy electrodes 620.

Optionally, the first-type electrodes 621 may be extended and formed along the second preset direction K, or the second-type electrodes 622 may be extended and formed along the first preset direction J. Extension directions of the first-type electrodes 621 and the second-type electrodes 622 are reasonably arranged, to further better utilize the size of the isolation structure 300 between the adjacent isolation openings 300b in the first preset direction J and the second preset direction K to arrange the dummy electrodes 620.

In some optional embodiments, the first-type electrodes 621 are distributed at intervals in the second preset direction K, or the second-type electrodes 622 are distributed at intervals in the first preset direction J.

Optionally, the light-transmitting openings 300a may be located between two of the first-type electrodes 621 adjacent in the second preset direction K and two of the second-type electrodes 622 adjacent in the first preset direction J.

In these optional embodiments, the first-type electrodes 621 are distributed at intervals in the second preset direction K, and the second-type electrodes 622 are distributed at intervals in the first preset direction J, so that there may be a certain interval space between the first-type electrodes 621 and the second-type electrodes 622 to facilitate the arrangement of the light-transmitting openings 300a. The light-transmitting openings 300a are arranged between two of the first-type electrodes 621 adjacent in the second preset direction K and two of the second-type electrodes 622 adjacent in the first preset direction J, so that a plurality of isolation openings 300b can better surround the periphery of the light-transmitting openings 300a, and the light-transmitting openings 300a may be arranged above part of the isolation structure 300 with a large size between the plurality of isolation openings 300b, so as to facilitate the arrangement of the light-transmitting openings 300a with large sizes, thereby better improving compactness of arrangement of the isolation openings 300b, the light-transmitting openings 300a, and the dummy electrodes 620. Moreover, part of the isolation structure 300 between two adjacent isolation openings 300b may not be provided with the dummy electrode 620 and the light-transmitting opening 300a at the same time, which can alleviate the problem of easy blocking of the light-transmitting opening 300a or the isolation opening 300b when the manufacturing process of the dummy electrode 620 varies, and there may be a smaller gap between two adjacent isolation openings 300b to facilitate arrangement of larger or more isolation openings 300b, thereby improving the display effect of the display panel 10.

In some embodiments of the present application, the first direction Y and the second direction Z may be the main extension directions of the entire display panel 10, and a user may mainly view light-emitting display content of the display panel 10 in the first direction Y and the second direction Z.

Optionally, the relative position relationships between the first direction Y, the second direction Z, the first preset direction J, and the second preset direction K may be set in variety of manners. Specifically, the relative positions of the first direction Y, the second direction Z, the first preset direction J, and the second preset direction K may be set according to a specific shape of the isolation opening 300b.

Optionally, the isolation opening 300b may be shaped in a variety of manners. For example, an orthographic projection of an inner wall of the isolation structure 300 enclosing the isolation opening 300b on the array substrate 100 may be in a shape of a polygon, a circle, an ellipse, a combination of a plurality of shapes, an irregular shape, or the like.

As shown in FIG. 6 and FIG. 7, in some embodiments, the first preset direction J may be parallel to the first direction Y, and the second preset direction K may be parallel to the second direction Z. That is, the isolation openings 300b may be distributed at intervals along a length direction and a width direction of the display panel.

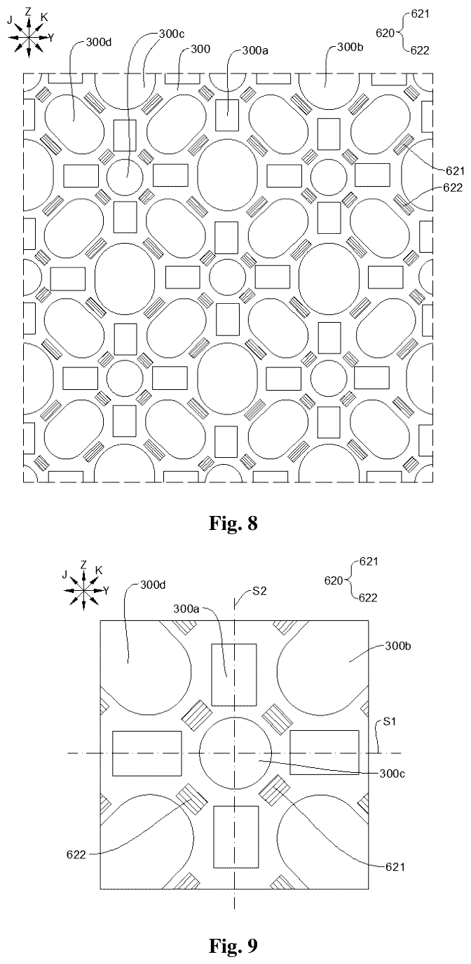

FIG. 8 shows a schematic partial view of the isolation structure 300 and the dummy electrode 620 according to an embodiment of the present application.

As shown in FIG. 8, in some other embodiments, the first preset direction J may intersect the first direction Y, and the second preset direction K may intersect the second direction Z, so as to better arrange the isolation openings according to the specific shape of the isolation openings 300b.

Optionally, an angle between the first preset direction J and the first direction Y may range from 30° to 60°, and an angle between the second preset direction K and the second direction Z may also range from 30° to 60°, so that the arrangement of the isolation openings 300b can also be relatively uniform in the first direction Y and the second direction Z, which may be less likely affect color shift of the display panel in the first direction Y and the second direction Z.

Optionally, the angle between the first preset direction J and the first direction Y may be 45°, and the angle between the second preset direction K and the second direction Z may also be 45°. In addition, the angle between the first preset direction J and the first direction Y may be 40° or 50°, and the angle between the second preset direction K and the second direction Z may also be 40° or 50°, which are not specifically limited herein.

In some optional embodiments, the at least two dummy electrodes 620 are arranged symmetrically with respect to a first symmetry axis S1, or the at least two dummy electrodes 620 are arranged symmetrically with respect to a second symmetry axis S2. The first symmetry axis S1 extends along the first direction Y and passes through geometric centers of the isolation openings 300b, and the second symmetry axis S2 extends along the second direction Z and passes through the geometric centers of the isolation openings 300a.

As shown in FIG. 6 and FIG. 7, optionally, when the first preset direction J is parallel to the first direction Y and the second preset direction K is parallel to the second direction Z, at least two first-type electrodes 621 on the periphery of at least part of the isolation openings 300b may be arranged symmetrically with respect to the second symmetry axis S2, and at least two second-type electrodes 622 on the periphery of at least part of the isolation openings 300b may be arranged symmetrically with respect to the first symmetry axis S1.

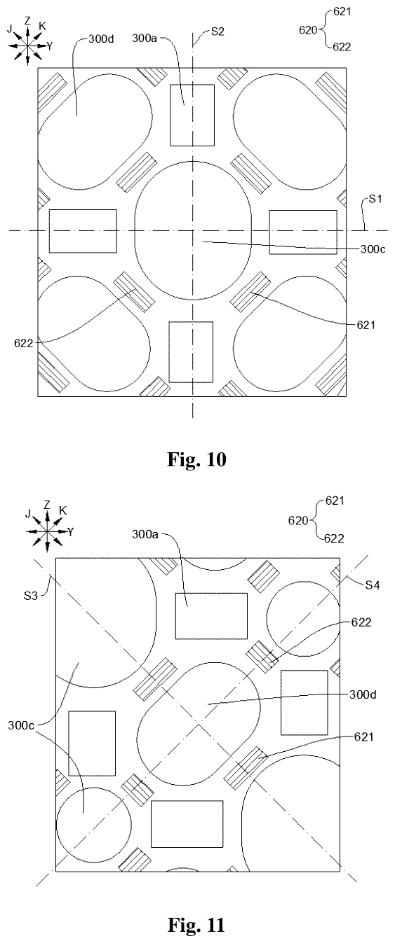

FIG. 9 shows a schematic partial enlarged view of the isolation structure 300 and the dummy electrode 620 according to yet another embodiment of the present application, and FIG. 10 shows a schematic partial enlarged view of the isolation structure 300 and the dummy electrode 620 according to still another embodiment of the present application.

As shown in FIG. 8 to FIG. 10, optionally, when the first preset direction J intersects the first direction Y and the second preset direction K intersects the second direction Z, the first-type electrodes 621 on the periphery of at least part of the isolation openings 300b may be arranged symmetrically with the second-type electrodes 622 on the periphery of the isolation openings 300b with respect to the first symmetry axis S1, or the first-type electrodes 621 on the periphery of at least part of the isolation openings 300b may be arranged symmetrically with the second-type electrodes 622 on the periphery of the isolation openings 300b with respect to the second symmetry axis S2.

The dummy electrodes 620 are arranged symmetrically with respect to the first symmetry axis S1 and the second symmetry axis S2, so that the dummy electrodes 620 on the periphery of the isolation openings 300b can be arranged relatively uniformly and the symmetrical dummy electrodes 620 have similar effects on the color shift of the light-emitting units 410 in the isolation openings 300b, so as to better reduce the color shift in the second area AA2, thereby better improving display uniformity of the second area AA2.

As shown in FIG. 9 and FIG. 10, in some optional embodiments, the light-emitting units 410 may include first light-emitting units, the isolation openings 300b may include first-type openings 300c accommodating the first light-emitting units, and the first-type openings 300c may be arranged symmetrically with respect to the first symmetry axis S1 or the second symmetry axis S2.

A plurality of light-transmitting openings 300a are arranged around a same first-type opening 300c, for the plurality of light-transmitting openings 300a arranged around the same first-type opening 300c, connecting lines of geometric center points of the plurality of light-transmitting openings 300a form a virtual polygon, and the first symmetry axis S1 or the second symmetry axis S2 are/is diagonals/a diagonal of the virtual polygon. In the embodiments shown in FIG. 9 and FIG. 10, four light-transmitting openings 300a are arranged around a same first-type opening 300c, connecting lines of geometric center points of the four light-transmitting openings 300a form a virtual quadrilateral, and the first symmetry axis S1 and the second symmetry axis S2 are two diagonals of the virtual quadrilateral, respectively.

In the above embodiments, the positions of the first-type openings 300c and the dummy electrodes 620 are reasonably set and the dummy electrodes 620 are arranged on the periphery of the first-type openings 300c relatively uniformly, so that the dummy electrodes 620 have similar effects on the color shift of the first light-emitting units in the first-type openings 300c, thereby better reducing the color shift in the second area AA2.

Optionally, the first light-emitting units emit red light or blue light. For example, as shown in FIG. 9, part of the first-type openings 300c may be configured to accommodate the first light-emitting units that emit red light. In another example, as shown in FIG. 10, part of the first-type openings 300c may be configured to accommodate the first light-emitting units that emit blue light.

FIG. 11 shows a schematic partial enlarged view of the isolation structure 300 and the dummy electrode 620 according to a further embodiment of the present application.

As shown in FIG. 11, in some optional embodiments, the light-emitting units 410 include second light-emitting units, the isolation openings 300b include second-type openings 300d accommodating the second light-emitting units, and the second-type openings 300d are arranged symmetrically with respect to a third symmetry axis S3 or a fourth symmetry axis S4. The third symmetry axis S3 extends along the first preset direction J and passes through geometric centers of the second-type openings 300d, and the fourth symmetry axis S4 extends along the second preset direction K and passes through the geometric centers of the second-type openings 300d.

When the first preset direction J intersects the first direction Y and the second preset direction K intersects the second direction Z, the second-type openings 300d are arranged symmetrically with respect to the third symmetry axis S3 or the fourth symmetry axis S4, that is, shapes of the second-type openings 300d are reasonably set, which facilitates the arrangement of the second-type openings 300d, so that the isolation structure 300 can be better arranged in the first preset direction J and the second preset direction K.

In some optional embodiments, the at least two dummy electrodes 620 are arranged symmetrically with respect to the third symmetry axis S3, or the at least two dummy electrodes 620 are arranged symmetrically with respect to the fourth symmetry axis S4.

Optionally, at least two dummy electrodes 620 on the periphery of the second-type opening 300d are arranged symmetrically with respect to the third symmetry axis S3, or the at least two dummy electrodes 620 on the periphery of the second-type opening 300d are arranged symmetrically with respect to the fourth symmetry axis S4.

In these optional embodiments, the at least two dummy electrodes 620 are arranged symmetrically with respect to the third symmetry axis S3 and the at least two dummy electrodes 620 are arranged symmetrically with respect to the fourth symmetry axis S4, so that the dummy electrodes 620 can be arranged on the periphery of the second-type openings 300d relatively uniformly and the dummy electrodes 620 have similar effects on the color shift of the second light-emitting units in the second-type openings 300d, thereby better reducing the color shift in the second area AA2.

Optionally, the second light-emitting units emit green light, and the second-type openings 300c may be configured to accommodate the second light-emitting units that emit green light.

In some embodiments of the present application, the crosstalk between the touch signal in the touch electrode 610 and the signal in the array substrate 100 may be further reduced by adjusting a relative position relationship or relative area relationship between the touch area 600a and the non-touch area 600b. For example, the crosstalk between the touch signal in the touch electrode 610 and the signal in the array substrate 100 may be reduced by adjusting a distance between the touch electrode 610 and the light-transmitting opening 300a.

Optionally, a minimum spacing between an orthographic projection of an inner wall of the isolation structure 300 enclosing the light-transmitting opening 300a on the array substrate 100 and the orthographic projection of the touch electrode 610 on the array substrate 100 is greater than or equal to 50 μm, so that there is a sufficient spacing between the position of the touch electrode 610 and the light-transmitting opening 300a and the signal in the array substrate 100 is less likely to affect the touch signal in the touch electrode 610 at a greater distance through the light-transmitting opening 300a. Therefore, the crosstalk between the touch signal in the touch electrode 610 and the signal in the array substrate 100 can be better reduced.

Optionally, a maximum spacing between boundaries of the non-touch area 600b may be less than or equal to 3 mm. For example, a dimension of the non-touch area 600b in any direction perpendicular to the thickness direction X of the display panel 10 may be less than or equal to 3 mm, so that the dummy electrode 620 may not have an excessively large area to affect the overall touch sensing capability of the display panel 10. Moreover, although the dummy electrode 620 in the non-touch area 600b in this range cannot participate in the touch sensing, a touch report point in the non-touch area 600b can be compensated for reasonably setting an algorithm of a touch control circuit in the display apparatus, so that the display panel 10 can still have a good touch sensing capability.

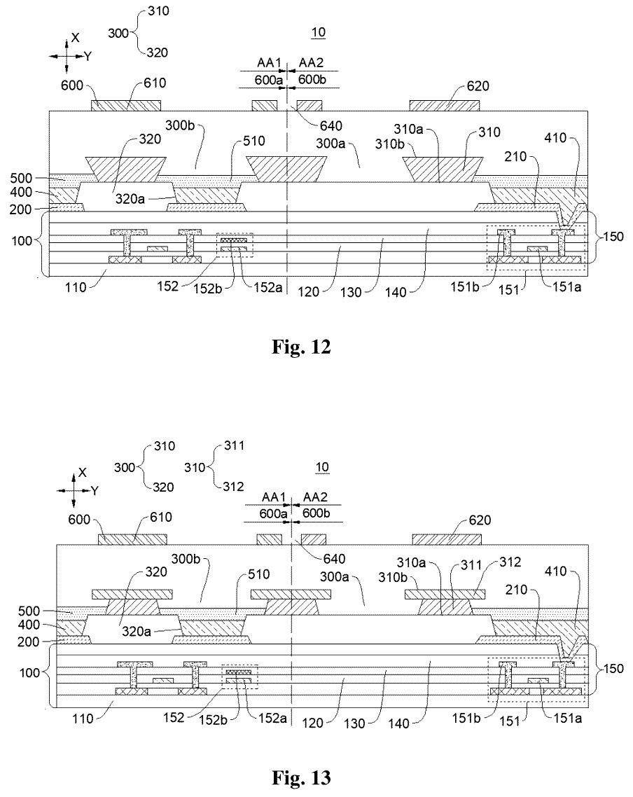

FIG. 12 shows is a partial sectional view of the display panel 10 according to another embodiment of the present application.

As shown in FIG. 12, in some optional embodiments, the isolation structure 300 may include a pixel defining portion 320, and the pixel defining portion 320 may be located between adjacent second electrodes 210, so that short-circuit connections are less likely to occur between adjacent second electrodes 210, thereby improving reliability of the light-emitting display of the display panel 10.

Optionally, the pixel defining portion 320 may be configured to divide sub-pixels of the display panel 10. For example, the isolation openings 300b may include pixel openings 320a provided in the pixel defining portion 320, at least part of the second electrodes 210 may be exposed from the pixel openings 320a, and at least part of the light-emitting units 410 may be located within the pixel openings 320a, so that at least part of the second electrodes 210 can be exposed from the pixel openings 320a to be in contact with the light-emitting units 410, thereby realizing the light-emitting display of the display panel 10.

As shown in FIG. 12, in some optional embodiments, the isolation structure 300 may include an isolation pillar 310, the isolation pillar 310 has a first end portion 310a and a second end portion 310b opposite to each other in the thickness direction X of the display panel 10, the second end portion 310b is located on a side of the first end portion 310a facing away from the array substrate 100, and an orthographic projection of the first end portion 310a on the array substrate 100 is located within an orthographic projection of the second end portion 310b on the array substrate 100.

The orthographic projection of the first end portion 310a of the isolation pillar 310 on the array substrate 100 is located within the orthographic projection of the second end portion 310b of the isolation pillar 310 on the array substrate 100, so that when the light-emitting layer 400 of the display panel 10 is vapor deposited, the second end portion 310b can block at least part of the materials used to manufacture the light-emitting layer 400 to partition the light-emitting layer 400 between adjacent sub-pixels and facilitate formation of a plurality of light-emitting units 410 arranged at intervals. Therefore, when the light-emitting layer 400 of the display panel 10 is vapor deposited, no fine mask is needed. For example, when the light-emitting layer 400 is vapor deposited, no fine metal mask (FMM) is needed, thereby reducing manufacturing costs of display panel 10.

In the embodiments of the present application, the isolation pillar 310 may shaped in a variety of manners. That is, there are a variety of manners to achieve that the orthographic projection of the first end portion 310a on the array substrate 100 is located within the orthographic projection of the second end portion 310b on the array substrate 100.

As shown in FIG. 12, in some embodiments, in a direction away from the array substrate 100, a spacing between surfaces on two sides of the isolation pillar 310 facing the isolation opening 300b gradually increases, so that the orthographic projection of the first end portion 310a of the isolation pillar 310 on the substrate may be located within the orthographic projection of the second end portion 310b of the isolation pillar 310 on the substrate.

FIG. 13 shows a partial sectional view of the display panel 10 according to yet another embodiment of the present application.

As shown in FIG. 13, in some other embodiments, the isolation pillar 310 includes a first isolation portion 311 and a second isolation portion 312 arranged on a side of the first isolation portion 311 facing away from the array substrate 100, and an orthographic projection of the first isolation portion 311 on the array substrate 100 is located within an orthographic projection of the second isolation portion 312 on the array substrate 100.

Optionally, the first end portion 310a may be located at the first isolation portion 311, and the second end portion 310b may be located at the second isolation portion 312. Optionally, the second isolation portion 312 protrudes from the first isolation portion 311 towards the isolation opening 300b.

In this embodiment, the orthographic projection of the first isolation portion 311 on the substrate is located within the orthographic projection of the second isolation portion 312 on the substrate, so that when the light-emitting layer 400 of the display panel 10 is vapor deposited, the second isolation portion 312 can block at least part of the materials used to manufacture the light-emitting layer 400 to partition the light-emitting layer 400 between adjacent sub-pixels and facilitate formation of a plurality of light-emitting units 410 arranged at intervals. Therefore, when the light-emitting layer 400 of the display panel 10 is vapor deposited, no fine mask is needed. For example, when the light-emitting layer 400 is vapor deposited, no FMM is needed, thereby reducing manufacturing costs of display panel 10.

In some embodiments, a material of the first isolation portion 311 includes a conductive material, and two adjacent first electrodes 510 are connected through the first isolation portion 311, that is, the first electrodes 510 in adjacent isolation openings 300b may be connected to each other through the first isolation portion 311 to form a planar electrode, to facilitate the control for the first electrodes 510 in the display panel 10.

In some other embodiments, the material of the first isolation portion 311 may include an insulating material, and the first electrodes 510 in adjacent isolation openings 300b can be insulated from each other through the first isolation portion 311, so that the first electrodes 510 in each isolation opening 300b in the display panel 10 can be independently controlled.

In some embodiments of the present application, the relative position between the isolation pillar 310 and the pixel defining portion 320 may be set in a variety of manners.

As shown in FIG. 13, in some embodiments, the isolation pillar 310 may be directly arranged on the pixel defining portion 320. That is, the isolation pillar 310 may be arranged on a side of the pixel defining portion 320 facing away from the array substrate 100.

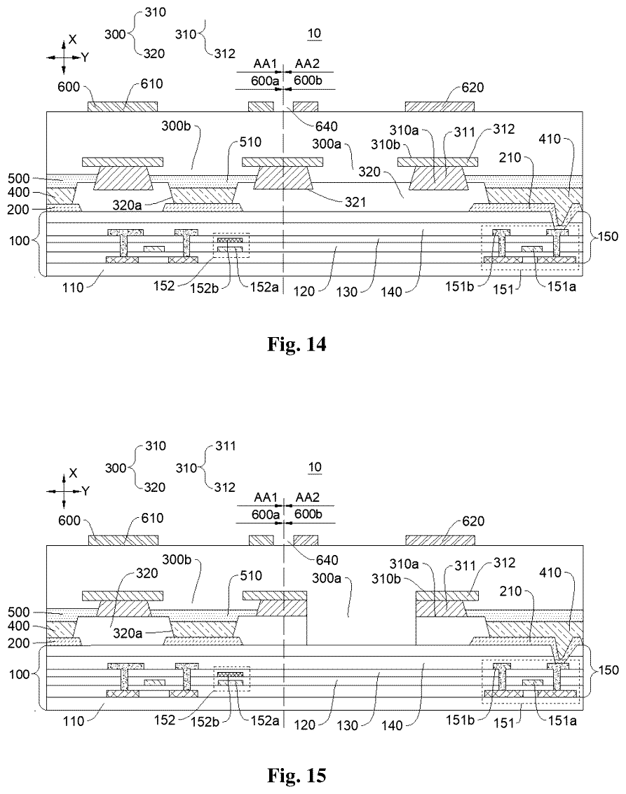

FIG. 14 shows a partial sectional view of the display panel 10 according to still another embodiment of the present application.

As shown in FIG. 14, in some other embodiments, the pixel defining portion 320 is provided with an accommodating groove 321, and at least part of the isolation pillar 310 may be arranged in the accommodating groove 321, so that the isolation structure 300 is less likely to have an excessive height compared with the array substrate 100. Therefore, the thickness of the display panel 10 can be better reduced.

As shown in FIG. 14, optionally, the light-transmitting opening 300a may be arranged through the isolation pillar 310, so as to better reduce blocking of light by the isolation pillar 310, so that the photosensitive component under the light-transmitting opening 300a can better sense the light.

FIG. 15 shows a partial sectional view of the display panel 10 according to a further embodiment of the present application.

As shown in FIG. 15, optionally, the light-transmitting opening 300a may be arranged through the isolation pillar 310 and the pixel defining portion 320, so as to further reduce the blocking of the light by the isolation structure 300 and further improve efficiency of light sensing of the photosensitive component under the light-transmitting opening 300a.

In some embodiments of the present application, an inner wall surface of the light-transmitting opening 300a may be shaped in a variety of manners. As shown in FIG. 14, in some embodiments, a shape of a surface on a side of the isolation structure 300 facing the light-transmitting opening 300a may be the same as a shape of a surface on a side of the isolation structure 300 facing the isolation opening 300b, so that when the isolation structure 300 is manufactured, the isolation opening 300b and the light-transmitting opening 300a may be made using a same manufacturing process, and the isolation opening 300b and the light-transmitting opening 300a may be manufactured together in a same manufacturing step. Therefore, efficiency of manufacturing of the display panel 10 can be better improved.

As shown in FIG. 15, in some other embodiments, the shape of the surface on the side of the isolation structure 300 facing the light-transmitting opening 300a may be different from the shape of the surface on the side of the isolation structure 300 facing the isolation opening 300b. The specific shape of the inner wall surface of the light-transmitting opening 300a may be set according to a specific requirement for the light transmittance of the light-transmitting opening 300a, so that light within a specific angle range can better pass through the light-transmitting opening 300a, which facilitates the design of the light transmittance of the display panel 10.

The embodiments of a second aspect of the present application provide a display apparatus including the display panel 10 in any one of the above implementations. Since the display apparatus according to the embodiments of the second aspect of the present application includes the display panel 10 in any one of the embodiments of the first aspect, the display apparatus according to the embodiments of the second aspect of the present application has the beneficial effects of the display panel 10 in any one of the embodiments of the first aspect, which are not repeated herein.

The display apparatus in the embodiments of the present application includes, but is not limited to, a mobile phone, a personal digital assistant (PDA), a tablet computer, an e-book, a television, an access control, a smart fixed phone, a console, and other devices with a display function.

Optionally, the display apparatus may include a photosensitive component configured to sense light, and the photosensitive component may be arranged corresponding to the light-transmitting opening 300a. For example, an orthographic projection of at least part of the photosensitive component on the substrate is within an orthographic projection of an inner wall of the isolation structure 300 enclosing the light-transmitting opening 300a on the substrate, so that light can be better sensed by the photosensitive component through the light-transmitting opening 300a.

Optionally, the photosensitive component may be arranged in a variety of types. For example, the photosensitive component may include a component that can sense light such as a range sensor, a camera, or an under-screen fingerprint sensor.

The above are merely specific implementations of the present application. It may be clearly understood by those skilled in the art that, for the purpose of convenient and brief description, specific operating processes of the foregoing system, module, and unit may be obtained with reference to the corresponding processes in the foregoing method embodiments, and details are not described herein again. It should be understood that the protection scope of the present application is not limited thereto. Any person skilled in the art may readily figure out various modifications or replacements within the technical scope disclosed in the present application, all of which should be encompassed within the protection scope of the present application.

What is claimed is:

1. A display panel, comprising a first area and a second area, wherein the display panel comprises:
an array substrate;
an isolation structure arranged on one side of the array substrate and provided with light-transmitting openings and isolation openings, the isolation openings being located at least in the first area, and the light-transmitting openings being located in the second area;
a light-emitting layer comprising light-emitting units arranged in the isolation openings; and
a touch layer arranged on a side of the light-emitting layer facing away from the array substrate and comprising a touch area and a non-touch area, the touch layer comprising a touch electrode arranged in the touch area and a dummy electrode arranged in the non-touch area, the touch electrode being insulated from the dummy electrode, at least part of the touch area being located in the first area, and at least part of the non-touch area being located in the second area.

2. The display panel of claim 1, wherein a light transmittance of the second area is greater than a light transmittance of the first area.

3. The display panel of claim 1, wherein the isolation openings are further located in the second area, and in the second area, the light-transmitting openings are located between adjacent isolation openings; and
the isolation openings in the first area and the second area are all provided with the light-emitting units.

4. The display panel of claim 1, wherein the touch area is arranged around at least part of the non-touch area; and
an orthographic projection of an inner wall of the isolation structure enclosing the light-transmitting opening on the touch layer is located in the non-touch area.

5. The display panel of claim 1, wherein
an orthographic projection of the dummy electrode on the isolation structure is arranged around one part of the isolation openings, and an orthographic projection of the touch electrode on the isolation structure is arranged around the other part of the isolation openings;
the orthographic projection of the dummy electrode on the isolation structure is arranged around at least part of the light-transmitting openings; and
the dummy electrode is a mesh in shape, and the touch electrode is a mesh in shape.

6. The display panel of claim 1, wherein
at least two dummy electrodes are provided, and adjacent dummy electrodes are arranged at intervals;
a plurality of the isolation openings is distributed at intervals in a first preset direction and a second preset direction, one part of the dummy electrodes is located between the isolation openings adjacent in the first preset direction, and the other part of the dummy electrodes is located between the isolation openings adjacent in the second preset direction, wherein the first preset direction intersects the second preset direction;
the dummy electrodes comprise first-type electrodes and second-type electrodes, the first-type electrodes are located between the isolation openings adjacent in the first preset direction, and the second-type electrodes are located between the isolation openings adjacent in the second preset direction;
the first-type electrodes are extended and formed along the second preset direction, or the second-type electrodes are extended and formed along the first preset direction;
the first-type electrodes are distributed at intervals in the second preset direction, or the second-type electrodes are distributed at intervals in the first preset direction;
the light-transmitting openings are located between two of the first-type electrodes adjacent in the second preset direction and two of the second-type electrodes adjacent in the first preset direction; and
the at least two dummy electrodes are arranged symmetrically with respect to a first symmetry axis, or the at least two dummy electrodes are arranged symmetrically with respect to a second symmetry axis, wherein the first symmetry axis extends along a first direction and passes through geometric centers of the isolation openings, the second symmetry axis extends along a second direction and passes through the geometric centers of the isolation openings, and the first direction intersects the second direction.

7. The display panel of claim 6, wherein the light-emitting units comprise first light-emitting units, the isolation openings comprise first-type openings accommodating the first light-emitting units, and the first-type openings are arranged symmetrically with respect to the first symmetry axis or the second symmetry axis;
a plurality of the light-transmitting openings is arranged around a same first-type opening, for the plurality of light-transmitting openings arranged around the same first-type opening, connecting lines of geometric center points of the plurality of light-transmitting openings form a virtual polygon, and the first symmetry axis or the second symmetry axis is a diagonal of the virtual polygon;
the first light-emitting units emit red light or blue light; and
an angle between the first direction and the first preset direction ranges from 30° to 60°, and an angle between the second direction and the second preset direction ranges from 30° to 60°.

8. The display panel of claim 7, wherein the angle between the first direction and the first preset direction is 45°, and the angle between the second direction and the second preset direction is 45°;
the light-emitting units comprise second light-emitting units, the isolation openings comprise second-type openings accommodating the second light-emitting units, and the second-type openings are arranged symmetrically with respect to a third symmetry axis or a fourth symmetry axis, wherein the third symmetry axis extends along the first preset direction and passes through geometric centers of the second-type openings, and the fourth symmetry axis extends along the second preset direction and passes through the geometric centers of the second-type openings; and
the at least two dummy electrodes are arranged symmetrically with respect to the third symmetry axis, or the at least two dummy electrodes are arranged symmetrically with respect to the fourth symmetry axis; and preferably, the second light-emitting units emit green light.

9. The display panel of claim 1, wherein
an orthographic projection of the dummy electrode on the array substrate is located within an orthographic projection of the isolation structure on the array substrate;
or
an orthographic projection of the touch electrode on the array substrate is located within the orthographic projection of the isolation structure on the array substrate.

10. The display panel of claim 1, wherein a distance between an orthographic projection of the dummy electrode on the isolation structure and the light-transmitting opening is greater than or equal to 1.5 μm, or a minimum spacing between the orthographic projection of the dummy electrode on the isolation structure and the isolation opening is greater than or equal to 1.5 μm.

11. The display panel of claim 1, wherein the touch layer comprises an insulating portion arranged between the touch electrode and the dummy electrode;
the insulating portion is arranged around at least part of the non-touch area;
an orthographic projection of the insulating portion on the array substrate is located within an orthographic projection of the isolation structure on the array substrate; and
a dimension of the insulating portion in a thickness direction of the display panel is equal to a dimension of the touch electrode in the thickness direction of the display panel, or the dimension of the insulating portion in the thickness direction of the display panel is equal to a dimension of the dummy electrode in the thickness direction of the display panel.

12. The display panel of claim 1, wherein the touch layer comprises a partition groove arranged between the touch electrode and the dummy electrode;
the partition groove is arranged through the touch layer; and
the partition groove is arranged around at least part of the non-touch area.

13. The display panel of claim 1, wherein the light-transmitting opening is located between two adjacent isolation openings.

14. The display panel of claim 1, wherein at least two light-transmitting openings are provided, and the at least two light-transmitting openings are arranged at intervals; and
the at least two light-transmitting openings are arranged at intervals in a first direction, or the at least two light-transmitting openings are arranged at intervals in a second direction, wherein the first direction, the second direction, and a thickness direction of the display panel pairwise intersect.

15. The display panel of claim 1, wherein a minimum spacing between an orthographic projection of an inner wall of the isolation structure enclosing the light-transmitting opening on the array substrate and an orthographic projection of the touch electrode on the array substrate is greater than or equal to 50 μm.

16. The display panel of claim 1, wherein the touch electrode is connected to a touch signal line of the display panel to receive a touch signal.

17. The display panel of claim 1, wherein the isolation structure comprises an isolation pillar, the isolation pillar has a first end portion and a second end portion opposite to each other in a thickness direction of the display panel, the second end portion is located on a side of the first end portion facing away from the array substrate, and an orthographic projection of the first end portion on the array substrate is located within an orthographic projection of the second end portion on the array substrate; and
in a direction away from the array substrate, a spacing between surfaces on two sides of the isolation pillar facing the isolation opening gradually increases.

18. The display panel of claim 17, wherein the isolation pillar comprises a first isolation portion and a second isolation portion arranged on a side of the first isolation portion facing away from the array substrate, and an orthographic projection of the first isolation portion on the array substrate is located within an orthographic projection of the second isolation portion on the array substrate;
the second isolation portion protrudes from the first isolation portion towards the isolation opening;
a material of the first isolation portion comprises a conductive material, the display panel further comprises a first electrode layer, the first electrode layer comprises at least two first electrodes arranged in the isolation opening and located on a side of the light-emitting unit facing away from the array substrate, and two adjacent first electrodes are connected through the first isolation portion; and
the light-transmitting opening is arranged through the isolation pillar.

19. The display panel of claim 17, wherein the display panel further comprises a second electrode layer, the second electrode layer comprises at least two second electrodes arranged at intervals, and the second electrodes are located on a side of the light-emitting unit facing the array substrate;
the isolation structure comprises a pixel defining portion located between adjacent second electrodes;
the light-transmitting opening is arranged through the isolation pillar and the pixel defining portion; and
the isolation pillar is arranged on a side of the pixel defining portion facing away from the array substrate, or the pixel defining portion is provided with an accommodating groove, and at least part of the isolation pillar is arranged in the accommodating groove.

20. A display apparatus, comprising the display panel of claim 1.
